(19) United States
(12) Patent Application Publication
(10) Pub. No.: US 2009/0261843 A1
(43) Pub. Date: Oct. 22, 2009

(54) LOAD SIMULATOR

(75) Inventor: BIN LI, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/202,346

(22) Filed: Sep. 1, 2008

(30) Foreign Application Priority Data
Apr. 18, 2008 (CN) 200810301212.8

(51) Int. Cl. G01R 31/02

(52) U.S. Cl. 324/555

(57) ABSTRACT

A load simulator includes an indicator, a first resistor, and a second resistor. A first terminal of the indicator is connected to a first pin of a charger, while a second terminal of the indicator is grounded. The indicator and the first resistor are connected in parallel. Two terminals of the second resistor are connected to a second pin of the charger and ground, respectively.

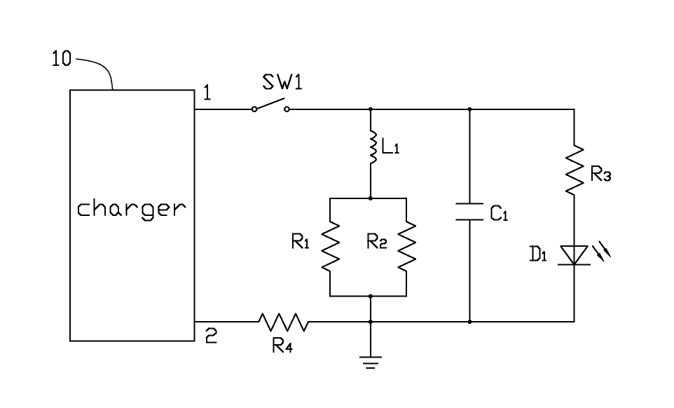

### BACKGROUND

1. Field of the Invention

The present disclosure relates to a load simulator, and particularly to a load simulator for simulating a battery.

2. Description of Related Art

It is essential to test the reliability of electronic products as a part of the production process. In general, batteries may act as loads in testing a battery charger. In one such testing process, the battery charger may automatically shut off when the battery is fully charged, thereby making it difficult to test the maximum working time of the charger. Additionally, batteries tend to overcharge, which may result in damaged batteries. As a result, using a battery as the load may not be suitable for testing the battery charger.

What is needed, therefore, is a safe and proper load device for testing a battery charger.

### SUMMARY

An exemplary load simulator includes an indicator, a first resistor, and a second resistor. A first terminal of the indicator is connected to a first pin of a charger, while a second terminal of the indicator is grounded. The indicator and the first resistor are connected in parallel. Two terminals of the second resistor are connected to a second pin of the charger and ground, respectively.

Other advantages and novel features of the present disclosure will become more apparent from the following detailed description when taken in conjunction with the accompanying drawing, in which:

### BRIEF DESCRIPTION OF THE DRAWING

The drawing is a load simulator in accordance with one embodiment of the present disclosure

### DETAILED DESCRIPTION

Referring to the drawing, a load simulator in accordance with one embodiment of the present disclosure includes a switch SW1, an inductor L1, a capacitor C1, a light emitting diode (LED) D1, and four resistors R1, R2, R3, and R4. The load simulator is designed for simulating a battery when testing a charger 10. The LED D1 may be used as an indicator to indicate a functional operation of the charger 10.

A first terminal of the switch SW1 is connected to a pin 1 of the charger 10, while a second terminal of the switch SW1 is connected to a first terminal of the inductor L1, a positive terminal of the capacitor C1, and a first terminal of the resistor R3. A second terminal of the inductor L1 is grounded through the resistors R1 and R2 connected in parallel. A negative terminal of the capacitor C1 is grounded. A second terminal of the resistor R3 is connected to a positive terminal of the LED D1, while a negative terminal of the LED D1 is grounded. Two terminals of the resistor R4 are connected to a pin 2 of the charger 10 and ground respectively. The resistors R1 and R2 are cement resistors. All elements mentioned above can be adjusted to provide a proper load for various chargers. For example, for a charger with 3.8V rated voltage and 0.45 A rated current, the resistance of the resistors R1, R2, R3, and R4 are 8Ω, 8Ω, 270Ω, and 10 k Ω respectively, the inductance of the inductor L1 is 68 μH, and the capacitance of the capacitor C1 is 22 μF. When the switch SW1 has been pressed to be in a closed position, the capacitor C1 provides a voltage for the LED D1. If the LED D1 emits light, the charger 10 is functioning as expected, and a timer is initiated. The charger 10 stops working when the LED D1 does not emit light. A value shown by the timer is the maximum working time of the charger 10.

A circuit, including the LED D1 and the resistors R1 and R4, can act as a load for the charger 10 in the above embodiment. Other elements, i.e., the switch SW1, the inductor L1, the capacitor C1, and the resistors R2 and R3, can be omitted. Additionally, the LED D1 can be substituted by other light or sound devices, such as a frequency divider.

The foregoing description of the disclosure has been presented only for the purposes of illustration and description and is not intended to be exhaustive or to limit the disclosure to the precise forms disclosed. Many modifications and variations are possible in light of the above teaching. Alternative embodiments will become apparent to those of ordinary skill in the art to which the present disclosure pertains without departing from its spirit and scope. Accordingly, the scope of the present disclosure is defined by the appended claims rather than the foregoing description and the embodiments described therein.

What is claimed is:

1. A load simulator comprising:
an indicator comprising an indicator first terminal capable of connecting to a first pin of a charger and an indicator second terminal connected to ground;
a first resistor connected in parallel with the indicator; and
a second resistor comprising a first terminal connected to a second pin of the charger and a second terminal connected to ground.

2. The load simulator as claimed in claim 1, wherein the indicator is a light emitting diode.

3. The load simulator as claimed in claim 1, wherein the indicator is a frequency divider.

4. The load simulator as claimed in claim 1, wherein the load simulator further comprises a switch comprising a switch first terminal and a switch second terminal, the switch first terminal is connected to the first pin of the charger, and the switch second terminal is connected to the indicator first terminal.

5. The load simulator as claimed in claim 4, wherein the load simulator further comprises an inductor comprising an inductor first terminal and an inductor second terminal, the inductor first terminal is connected to the switch second terminal, and the inductor second terminal is grounded through the first resistor.

6. The load simulator in claim 4, wherein the load simulator further comprises a capacitor comprising a capacitor positive terminal and a capacitor negative terminal, the capacitor positive terminal is connected to the switch second terminal, and the capacitor negative terminal is grounded.

7. The load simulator as claimed in claim 4, wherein the load simulator further comprises a third resistor comprising two terminals connected to the switch second terminal and the indicator first terminal, respectively.

8. The load simulator as claimed in claim 5, wherein the load simulator further comprises a fourth resistor connected in parallel with the first resistor.

9. The load simulator as claimed in claim 8, wherein the fourth resistor and the first resistor are cement resistors.
